(19) United States
(12) Patent Application Publication
(10) Pub. No.: US 2022/0326620 A1
(43) Pub. Date: Oct. 13, 2022

(54) PHOTORESIST STRIPPING COMPOSITION

(71) Applicant: Dow Global Technologies LLC, Midland, MI (US)

(72) Inventors: Qi Jiang, Shanghai (CN); Xue Chen, Manvel, TX (US); Xin Jiang, Shanghai (CN); Jianhai Mu, Shanghai (CN); Stephen W. King, Braselton, GA (US)

(21) Appl. No.: 17/635,138

(22) PCT Filed: Aug. 30, 2019
(86) PCT No.: PCT/CN2019/103609

§ 371 Date: Feb. 14, 2022

(51) Int. Cl. G03F 7/42; H01L 21/683

(52) U.S. Cl. CPC G03F 7/425; H01L 21/6836

(57) ABSTRACT

A photoresist stripping composition comprising an organic amine and a method is provided. The photoresist stripping composition comprising an organic amine having the following formula (1).

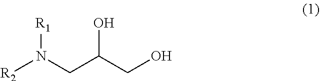

### FIELD OF THE INVENTION

The present disclosure relates to a photoresist stripping composition, in particular a photoresist stripping composition for electronic manufacturing applications.

### INTRODUCTION

Organic amines are widely used in a photoresist stripping and cleaning composition for electronic processing, such as a photoresist stripping composition for preparing RGB dyes in display, a photoresist stripping composition for a lithography process in semiconductor manufacturing, a photoresist stripping composition to remove a photoresist, a damaged photoresist layer, and a side-wall-protecting deposition film, etc., after dry or wet etching of wiring materials and electrode materials in the fabrication of semiconductor and display panel. The organic amines can dissolve many polar polymers, monomers, and compounds. However, the strong basic property of organic amines can cause the corrosion of metals such as copper and aluminum, thereby causing defects of the device such as wire board, semiconductor microchip and display pixel processed by a photoresist stripping and cleaning composition comprising an organic amine.

A conventional process for stripping or cleaning a photoresist is to dip a substrate with a photoresist into a photoresist stripping and cleaning composition. Recently, a spray stripping process is used for both semiconductor and display, in order to enhance the production efficacy, decrease the amount of the photoresist stripping and cleaning composition and facilitate the treatment of large devices such as a large semi-conductor wafer and a large-screen display. During the spray stripping process, the stripping composition is sprayed on the substrate. However, a conventional photoresist stripping composition cannot be applied into this spraying stripping process, because the photoresist cannot be removed completely.

There is a need to provide a photoresist stripping and cleaning composition with weaker metal corrosion but good dissolution to electronic materials such as a photoresist.

### SUMMARY OF THE INVENTION

The inventor has unexpectedly found that a photoresist stripping composition comprising a specific organic amine can have weaker metal corrosion but good dissolution to electronic materials such as a photoresist.

The present disclosure provides a photoresist stripping composition comprising an organic amine having the following formula (1):

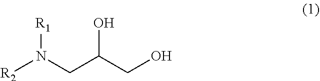

wherein R₁ and R₂ are each independently selected from the group consisting of hydrogen and C₁-C₅ alkyl.

The present disclosure further provides a method of stripping a photoresist, comprising:

(1) providing a substrate having a photoresist;

(2) spraying a photoresist stripping composition to the substrate or dipping the substrate into a photoresist stripping composition, wherein the photoresist stripping composition comprises an organic amine having the following formula (1):

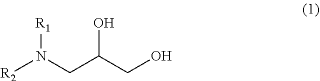

wherein R₁ and R₂ are each independently selected from the group consisting of hydrogen and C₁-C₅ alkyl.

The present disclosure further provides use of an organic amine in a photoresist stripping composition, wherein said organic amine has the following formula (1):

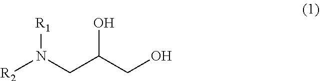

wherein R₁ and R₂ are each independently selected from the group consisting of hydrogen and C₁-C₅ alkyl.

### DETAILED DESCRIPTION OF THE INVENTION

As disclosed herein, the term “composition”, “formulation” or “mixture” refers to a physical blend of different components, which is obtained by mixing simply different components by a physical means.

As disclosed herein, the term “stripping” or “cleaning” or “removing” have the same meaning, i.e., a photoresist is removed from a substrate.

As disclosed herein, all the percentages and parts of all components of the composition refer to the weight. All the percentages of all components of the composition are calculated based on the total weight of the composition. The sum of the percentages of all the components of the composition is 100%.

As disclosure herein, the term “alkyl” refers to an alkyl group having 1 to 20 carbon atoms, typical 1 to 10 carbon atoms, more typical 1 to 6 carbon atoms, most typical 1 to 4 carbon atoms.

On one aspect, the present disclosure provides a photoresist stripping composition comprising an organic amine having the following formula (1):

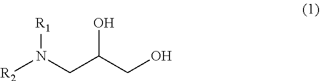

wherein R₁ and R₂ are each independently selected from the group consisting of hydrogen and C₁-C₅ alkyl.

In one embodiment, R₁ and R₂ are each independently selected from the group consisting of hydrogen and C₁-C₅ alkyl. In another embodiment, R₁ and R₂ are each independently selected from the group consisting of hydrogen and C₁-C₄ alkyl. In another embodiment, R₁ and R₂ are each independently selected from the group consisting of hydrogen and C₁-C₂ alkyl. In another embodiment, R₁ and R₂ are each independently selected from the group consisting of hydrogen and C₁ alkyl. In another embodiment, R₁ and R₂ are each independently selected from the group consisting of hydrogen, methyl, ethyl, isopropyl, propyl, isobutyl and butyl.

In the formula (1) above, the term “C₁-C₅ alkyl” refers to a linear or branched alkyl group having 1 to 4 carbon atoms, Preferably, the term “C₁-C₄ alkyl” comprises methyl, ethyl, propyl, isopropyl, isobutyl or butyl.

In embodiment, the organic amine having the above formula (1) comprises the following compounds:

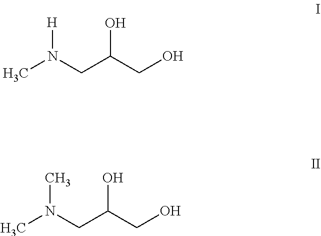

Generally, the photoresist stripping composition comprises 0.1-80wt % of said organic amine, typical 1-70wt %, more typical 5-60wt %, most typical 10-55wt %, based on the total weight of the photoresist stripping composition.

The composition may further comprise one or more glycol ethers. Examples of the glycol ethers may include ethylene glycol methyl ether, ethylene glycol ethyl ether, ethylene glycol butyl ether, diethylene glycol methyl ether, diethylene glycol ethyl ether, diethylene glycol butyl ether, diethylene glycol propyl ether, triethylene glycol methyl ether, triethylene glycol ethyl ether, triethylene glycol butyl ether, propylene glycol methyl ether, propylene glycol ethyl ether, propylene glycol butyl ether, dipropylene glycol methyl ether, dipropylene glycol ethyl ether, dipropylene glycol butyl ether, dipropylene glycol propyl ether, tripropylene glycol methyl ether, tripropylene glycol ethyl ether, tripropylene glycol butyl ether, etc.

In an exemplary embodiment, the composition of the present disclosure comprises 0-99.9wt % of one or more glycol ethers, typical 5-95wt %, more typical 10-90wt %, most typical 15-80wt %, based on the total weight of the composition.

The composition may further comprise water. In an exemplary embodiment, the composition of the present disclosure comprises 0-99.9wt % of a polar solvent, typical 10-90wt %, more typical 15-80wt %, most typical 20-75wt %, based on the total weight of the composition.

The photoresist stripping composition may further include a polar solvent including nitrogen. The polar solvent including nitrogen can decompose the photoresist pattern detached from the substrate into unit-molecules. The unit-molecule may be dissolved in the composition for removing a photoresist pattern. In particular, a functional group of the polar solvent includes nitrogen to assist the organic amine in penetrating into the photoresist pattern to convert the photoresist pattern to a gel state for removal. In addition, the polar solvent including nitrogen has a chemical attraction to the organic amine, thereby minimizing a component change due to vaporization of the composition for removing a photoresist.

Examples of the polar solvent including nitrogen may include N-alkyl-2-pyrrolidone such as N-methyl-2-pyrrolidone, N-methyl acetamide, N,N′-dimethyl acetamide, acetamide, N′-ethyl acetamide, N,N′-diethyl acetamide, formamide, N-methyl formamide, N,N′-dimethyl formamide, N-ethyl formamide, N,N′-diethyl formamide, N,N′-dimethyl imidazole, N-aryl formamide, N-butyl formamide, N-propyl formamide, N-pentyl formamide, N-methylpyrrolidone, etc.

The composition of the present disclosure may include 30-80wt % of the polar solvent including nitrogen, based on the total weight of the composition.

The composition of the present disclosure may further comprise a corrosion inhibitor. The corrosion inhibitor may include a compound containing a nitrogen atom, a sulfur atom, an oxygen atom, etc., which have an unshared electron pair. Particularly, the compound may contain a hydroxyl group, a hydrogen sulfide group, etc. A reacting group of the corrosion inhibitor may physically and chemically bond to a metal to prevent a corrosion of a metal thin layer including the metal.

The corrosion inhibitor includes a triazole compound. Examples of the triazole compound may include benzotriazole, tolyltrizole, etc.

The composition of the present disclosure may include 0.1-3wt % of the corrosion inhibitor, based on the total weight of the composition.

The composition of the present disclosure may further comprise a surfactant. The surfactant may be added in order to assist in both the lifting-off of insoluble photoresist residues and reduce silicon etching, which may occur under exposure to strong bases. Suitable surfactants include, but are not limited to, anionic, cationic, nonionic surfactants, such as fluoroalkyl surfactants, polyethylene glycols, polypropylene glycols, polyethylene or polypropylene glycol ethers, carboxylic acid salts, dodecylbenzenesulfonic acid or salts thereof, polyacrylate polymers, silicone or modified silicone polymers, acetylenic diols or modified acetylenic diols, alkylammonium or modified alkylammonium salts, as well as combinations comprising at least one of the foregoing surfactants.

In an exemplary embodiment, the composition of the present invention comprises 20wt % or less of the surfactant, typical 15wt % or less, more typical 1-10wt %, based on the total weight of the composition.

On another aspect, the present disclosure further provides a method of stripping a photoresist, comprising:

(1) providing a substrate having a photoresist;

(2) spraying a photoresist stripping composition to the substrate or dipping the substrate into a photoresist stripping composition, wherein the photoresist stripping composition comprises an organic amine having the following formula (1):

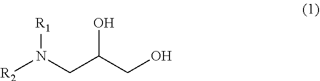

wherein R₁ and R₂ are each independently selected from the group consisting of hydrogen and C₁-C₅ alkyl.

The photoresist as used herein is generally applicable to any layer comprising photoresist. Thus, for example, in accordance with the teachings of the present disclosure, the composition and method herein may be used to remove photoresist as well as photoresist residue.

The substrate as used herein includes, but not limited to, a semiconductor wafer, a printed wire board, an OLED display and a liquid crystal display. Generally, the substrate may further comprise a metal interconnect, such as copper interconnect, molybdenum interconnect and aluminum interconnect.

In an embodiment, the method may further comprise a step of rinsing the substrate obtained in step (2) with water.

On another aspect, the present disclosure further provides use of an organic amine in a photoresist stripping composition, wherein said organic amine has the following formula (1):

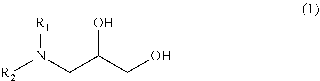

wherein R₁ and R₂ are each independently selected from the group consisting of hydrogen and C₁-C₅ alkyl.

The organic amine according to the present disclosure may inhibit the corrosion of interconnect metal such as copper, molybdenum and aluminum.

### EXAMPLES

### Materials

Photoresist: SFP-1400 solution (from MERCK).

Solvents: diethylene glycol butyl ether (from Dow Chemical Company, 99%).

Amines: 3-(dimethylamino)-1,2-propanediol (available from DU-HOPE INTERNATIONAL GROUP COMPANY; monoethanolamine, N-methylethanolamine, monoisopropanolamine and aminoethylethanolamine (all available from Dow Chemical Company, 99%)

Copper foil with thickness of 1 mm (from Alfa Aesar, 99.999%)

### Terminologies of Different Chemicals are Shown Below

BuCb: diethylene glycol butyl ether

DMAPD: 3-(dimethylamino)-1,2-propanediol

MEA: monoethanolamine

NMEA: N-methylethanolamine

MIPA: monoisopropanolamine

AEEA: aminoethylethanolamine

MAPD: 1-(Methylamino)-2,3-Propanediol (Adamas Reagent Co., Ltd Purity 98%)

### Examples 1-6 and Comparative Examples 1-24

The photoresist stripping compositions were prepared by mixing the components listed in Table 1 below:

TABLE 1

| | Component A | Weight % | Component B | Weight % | Component C | Weight % |
|---|---|---|---|---|---|---|
| Example | | | | | | |
| 1 | DMAPD | 20 | BuCb | 30 | water | 50 |
| 2 | DMAPD | 12 | BuCb | 18 | water | 70 |
| 3 | DMAPD | 50 | BuCb | 50 | | |
| 4 | DMAPD | 30 | BuCb | 70 | | |
| 5 | DMAPD | 50 | | | water | 50 |
| 6 | DMAPD | 30 | | | water | 70 |
| Comparative | | | | | | |
| Example | | | | | | |
| 1 | MEA | 20 | BuCb | 30 | water | 50 |
| 2 | MEA | 12 | BuCb | 18 | water | 70 |
| 3 | MEA | 50 | BuCb | 50 | | |
| 4 | MEA | 30 | BuCb | 70 | | |
| 5 | MEA | 50 | | | water | 50 |
| 6 | MEA | 30 | | | water | 70 |
| 7 | NMEA | 20 | BuCb | 30 | water | 50 |
| 8 | NMEA | 12 | BuCb | 18 | water | 70 |
| 9 | NMEA | 50 | BuCb | 50 | | |
| 10 | NMEA | 30 | BuCb | 70 | | |
| 11 | NMEA | 50 | | | water | 50 |
| 12 | NMEA | 30 | | | water | 70 |
| 13 | MIPA | 20 | BuCb | 30 | water | 50 |
| 14 | MIPA | 12 | BuCb | 18 | water | 70 |
| 15 | MIPA | 50 | BuCb | 50 | | |
| 16 | MIPA | 30 | BuCb | 70 | | |
| 17 | MIPA | 50 | | | water | 50 |
| 18 | MIPA | 30 | | | water | 70 |
| 19 | AEEA | 20 | BuCb | 30 | water | 50 |
| 20 | AEEA | 12 | BuCb | 18 | water | 70 |
| 21 | AEEA | 50 | BuCb | 50 | | |
| 22 | AEEA | 30 | BuCb | 70 | | |
| 23 | AEEA | 50 | | | water | 50 |
| 24 | AEEA | 30 | | | water | 70 |

### Example 7

2 mL of SFP-1400 photoresist solution was coated onto the surface of glass substrate with the size of 100 mm×100 mm×1 mm. The substrate was spun at the rotation speed of 500 rpm for 10 seconds, and then the rotation speed was accelerated to 1000 rpm and maintained for 30 seconds. The spin-coated substrate was baked at 130° C. for 10 min to evaporate the solvent completely and cure the photoresist film. In the following stripping step, 30 g of each above example or comparative example was prepared in a container. The baked substrate was put into the container at 22° C., with shaking Finally, the time was recorded for completely removing the photoresist from the substrate. The results were listed in Tables 2 and 3 below.

The photoresist stripping results of the examples or comparative examples were listed in the tables below. The performance was evaluated by stripping time. The shorter time it takes to remove photoresist film from the substrate, the better performance the stripping solutions have. Higher water content can shorten the stripping time. MEA, NMEA, MIPA and AEEA are typical organic amines used in the photoresist stripping composition. As shown in Tables 2 and 3, the stripping time was categorized into 4 groups for comparison. 3-(dimethylamino)-1,2-propanediol could provide similar performance

TABLE 2

| | | | | | | | |
|---|---|---|---|---|---|---|---|
| # | Component A | Weight % | Component B | Weight % | Component C | Weight % | Performance |

Example

| | | | | | | | |
|---|---|---|---|---|---|---|---|
| 1 | DMAPD | 20 | BuCb | 30 | water | 50 | O |

Comparative Example

| | | | | | | | |
|---|---|---|---|---|---|---|---|
| 1 | MEA | 20 | BuCb | 30 | water | 50 | ⊙ |
| 7 | NMEA | 20 | BuCb | 30 | water | 50 | ◯ |
| 13 | MIPA | 20 | BuCb | 30 | water | 50 | Δ |
| 19 | AEEA | 20 | BuCb | 30 | water | 50 | Δ |

⊙ <60 seconds;
◯ 60~65 seconds;
Δ 65~70 seconds;
X >70 seconds

TABLE 3

| | | | | | | | |
|---|---|---|---|---|---|---|---|
| # | Component A | Weight % | Component B | Weight % | Component C | Weight % | Performance |

Example

| | | | | | | | |
|---|---|---|---|---|---|---|---|
| 2 | DMAPD | 12 | BuCb | 18 | water | 70 | Δ |

Comparative Example

| | | | | | | | |
|---|---|---|---|---|---|---|---|
| 2 | MEA | 12 | BuCb | 18 | water | 70 | ◯ |
| 8 | NMEA | 12 | BuCb | 18 | water | 70 | Δ |
| 14 | MIPA | 12 | BuCb | 18 | water | 70 | Δ |
| 20 | AEEA | 12 | BuCb | 18 | water | 70 | X |

⊙ <30 seconds;
◯ 30~40 seconds;
Δ 40~50 seconds;
X >50 seconds

### Example 8

The highly pure copper foil with calendering thickness of 1 mm (from Alfa Aesar, 99.999%) was cut into squares with weight of 0.90±0.01 g. A copper oxide (CuO or Cu₂O) passivation layer was formed on the surface of the copper foil. The copper pieces were then immersed in a 5% HCl aqueous solution for 5 minutes in order to completely remove the passivation layer and ensure the 99.999% purity. The acid-treated copper pieces were rinsed with 20 mL DI water and dried by nitrogen gas flow. Each copper piece was put in a 10 mL glass bottle with 5 g formulation of the examples or comparative examples at 54° C. for 30 min. Then, the copper pieces were taken out. ICP-OES (PerkinElmer 5300DV) was used to determine the content of copper ions remaining in the solvent. The results were listed in Tables 4 and 5 below.

The amounts of copper ions in the formulations were detected to evaluate the copper corrosion performance The copper ions in ppm levels are also categorized into 4 groups. As shown in Tables 4 and 5, MEA, NMEA and MIPA caused serious copper corrosion because a large amount of copper ions in the liquid formulations were detected. The formulations comprising 3 -(dimethylamino)-1,2-propanediol and AEEA showed the retardant corrosion effect.

TABLE 4

| | | | | | |
|---|---|---|---|---|---|
| # | Component A | Weight % | Component B | Weight % | Performance |

Example

| | | | | | |
|---|---|---|---|---|---|
| 3 | DMAPD | 50 | BuCb | 50 | ◯ |
| 4 | DMAPD | 30 | BuCb | 70 | ⊙ |

Comparative Example

| | | | | | |
|---|---|---|---|---|---|
| 3 | MEA | 50 | BuCb | 50 | ◯ |
| 4 | MEA | 30 | BuCb | 70 | × |
| 9 | NMEA | 50 | BuCb | 50 | ◯ |
| 10 | NMEA | 30 | BuCb | 70 | × |
| 15 | MIPA | 50 | BuCb | 50 | Δ |
| 16 | MIPA | 30 | BuCb | 70 | × |
| 21 | AEEA | 50 | BuCb | 50 | ◯ |
| 22 | AEEA | 30 | BuCb | 70 | Δ |

⊙: <1 ppm; ◯: 1~2 ppm; Δ: 2~4 ppm; ×: >4 ppm

TABLE 5

| | | | | | |
|---|---|---|---|---|---|
| # | Component A | Weight % | Component C | Weight % | Performance |

Example

| | | | | | |
|---|---|---|---|---|---|
| 5 | DMAPD | 50 | water | 50 | ◯ |
| 6 | DMAPD | 30 | water | 70 | ⊙ |

Comparative Example

| | | | | | |
|---|---|---|---|---|---|
| 5 | MEA | 50 | water | 50 | ◯ |
| 6 | MEA | 30 | water | 70 | × |
| 11 | NMEA | 50 | water | 50 | ◯ |
| 12 | NMEA | 30 | water | 70 | × |
| 17 | MIPA | 50 | water | 50 | ◯ |
| 18 | MIPA | 30 | water | 70 | × |
| 23 | AEEA | 50 | water | 50 | ⊙ |
| 24 | AEEA | 30 | water | 70 | ⊙ |

⊙: <1 ppm; ◯: 1~2 ppm; Δ: 2~4 ppm; ×: >4 ppm

### Examples 9-13 and Comparative Examples 25-46

The highly pure copper foil with calendering thickness of 1 mm (from Alfa Aesar, 99.999%) was cut into 1 cm*1 cm pieces. The copper pieces were then immersed in a 2% HCl aqueous solution for 5 minutes in order to completely remove CuO or Cu₂O. Each copper piece was put in a 10 mL glass bottle with 5 g formulation of the examples or comparative examples in Tables 6 and 7 below. The bottles were quickly shaked for two or three minutes and then were kept in an oven at 60° C. for 4 hours. Then, the copper pieces were taken out. ICP-OES (PerkinElmer 5300DV) was used to determine the content of copper ions remaining in the solution. The results were listed in Tables 6 and 7 below.

TABLE 6

| Examples | MAPD, % | MEA, % | MIPA, % | NMEA, % | BuCb, % | Water, % | Cu Ion, ppm |
|---|---|---|---|---|---|---|---|
| Example 9 | 99.7 | / | / | / | / | 0 | 0.3 |
| Example 10 | 95.0 | / | / | / | / | 5.0 | 0.2 |
| Example 11 | 80.0 | / | / | / | / | 20.0 | 0.5 |
| Example 12 | 50.0 | / | / | / | / | 50.0 | 1.4 |
| Example 13 | 30 | / | / | / | 70 | 0 | 2.1 |
| Comparative | / | 99.7 | / | / | / | 0 | 21.8 |
| Example 25 | | | | | | | |
| Comparative | / | 95.0 | / | / | / | 5.0 | 13.0 |
| Example 26 | | | | | | | |
| Comparative | / | 80.0 | / | / | / | 20.0 | 13.6 |
| Example 27 | | | | | | | |
| Comparative | / | 50.0 | / | / | / | 50.0 | 13.0 |
| Example 28 | | | | | | | |
| Comparative | / | 30 | / | / | 70 | 0 | 50.0 |
| Example 29 | | | | | | | |
| Comparative | / | / | 99.7 | / | / | 0 | 37.5 |
| Example 30 | | | | | | | |
| Comparative | / | / | 95.0 | / | / | 5.0 | 36.6 |
| Example 31 | | | | | | | |
| Comparative | / | / | 80.0 | / | / | 20.0 | 26.4 |
| Example 32 | | | | | | | |
| Comparative | / | / | 50.0 | / | / | 50 | 19.2 |
| Example 33 | | | | | | | |
| Comparative | / | / | 30 | / | 70 | 0 | 126.0 |
| Example 34 | | | | | | | |
| Comparative | / | / | / | 99.7 | / | 0 | 38.7 |
| Example 35 | | | | | | | |
| Comparative | / | / | / | 95.0 | / | 5.0 | 26.0 |
| Example 36 | | | | | | | |
| Comparative | / | / | / | 80.0 | / | 20.0 | 7.8 |
| Example 37 | | | | | | | |
| Comparative | / | / | / | 50.0 | / | 50.0 | 4.3 |
| Example 38 | | | | | | | |
| Comparative | / | / | / | 30 | 70 | 0 | 131.0 |
| Example 39 | | | | | | | |
| Comparative | / | / | / | / | / | / | 11.0 |
| Example 40 | | | | | | | |

TABLE 7

| Examples | MAPD, % | MIPA, % | bis-imidazoline, % | bentzotriazole, % | Cu Ion, ppm |
|---|---|---|---|---|---|
| Example 9 | 99.7 | / | / | / | 0.3 |
| Comparative Example 41 | / | 99.9 | 0.1 | / | 41 |
| Comparative Example 42 | / | 99.5 | 0..5 | / | 35 |
| Comparative Example 43 | / | 99.0 | 1.0 | / | 33 |
| Comparative Example 44 | / | 99.9 | / | 0.1 | 29 |
| Comparative Example 45 | / | 99.5 | / | 0..5 | 18 |
| Comparative Example 46 | / | 99.0 | / | 1.0 | 16 |

What is claimed is:

1. A photoresist stripping composition comprising an organic amine having the following formula (1): 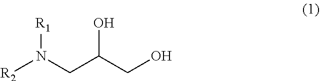
wherein R₁ and R₂ are each independently selected from the group consisting of hydrogen and C₁-C₅ alkyl.

2. The photoresist stripping composition of claim 1, wherein R₁ and R₂ are each independently selected from the group consisting of hydrogen and C₁-C₄ alkyl.

3. The photoresist stripping composition of claim 1, wherein R₁ and R₂ are each independently selected from the group consisting of hydrogen and C₁-C₂ alkyl.

4. The photoresist stripping composition of claim 1, wherein the organic amine having the above formula (1) comprises the following compounds:

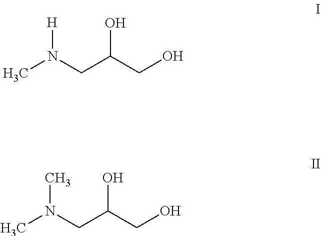

5. The photoresist stripping composition of claim 1, wherein the composition comprises water.

6. The photoresist stripping composition of claim 1, wherein the composition comprises one or more glycol ethers.

7. A method of stripping a photoresist, comprising:
(1) providing a substrate having a photoresist;
(2) spraying a photoresist stripping composition to the substrate or dipping the substrate into a photoresist stripping composition, wherein the photoresist stripping composition comprises an organic amine having the following formula (1): 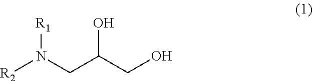
wherein R₁ and R₂ are each independently selected from the group consisting of hydrogen and C₁-C₅ alkyl.

8. The method of claim 7, wherein the substrate is selected from the group consisting of a semiconductor wafer, a printed wire board, an OLED display and a liquid crystal display.

9. Use of an organic amine in a photoresist stripping composition, wherein said organic amine has the following formula (1): 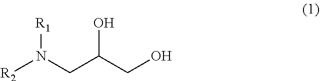
wherein R₁ and R₂ are each independently selected from the group consisting of hydrogen and C₁-C₅.

10. The use of claim 9, wherein said use comprise inhibiting the corrosion of interconnect metal.
